(19) United States
(12) Patent Application Publication
(10) Pub. No.: US 2010/0128899 A1
(43) Pub. Date: May 27, 2010

(54) LARGE RC TIME-CONSTANT GENERATION FOR AUDIO AMPLIFIERS

(75) Inventor: LANCE M. WONG, San Francisco, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NUVOTON TECHNOLOGY CORPORATION, Hsin-Chu (TW)

(21) Appl. No.: 12/324,749

(22) Filed: Nov. 26, 2008

(51) Int. Cl. H04B 15/00; H03K 4/04

(52) U.S. Cl. 381/94.5; 327/346

(57) ABSTRACT

A circuit for generating a large RC time-constant includes an input node for receiving an input signal making a transition from a first state to a second state characterized by a first time-constant, and an output node for providing an output signal making a transiting from the first state to the second state in response to the input signal. The circuit also includes a first MOS field effect transistor coupled between the input node and the output node. The circuit further includes a first capacitor coupled between the output node and a ground node. A switch circuit is connected to a gate of the first MOS field effect transistor. The switch circuit is configured to bias the MOS field effect transistor to operate in saturation mode and the transition of the output signal is characterized by a time-constant associated with this large output resistance and the capacitor coupled to the output node.

### BACKGROUND OF THE INVENTION

The present invention relates generally to electronic circuit techniques. More specifically, embodiments of the present invention relate to techniques for cost effective large time-constant generation. Merely by way of example, embodiments of the invention have been applied to audio amplifier and systems in applications, such as pop-noise suppression. But it would be recognized that the invention has a much broader range of applicability.

Amplifier circuits are prevalent in modern electronic devices. An electronic amplifier is a device for increasing the power and/or amplitude of a signal. In particular, power amplifier circuits are used at the output stage of a system to drive an external device, such as a speaker. Power amplifier circuits output stages can be classified as A, B, AB and C for analog designs, and class D and E for switching designs. This classification is based on the portion of the input signal cycle during which the amplifying device conducts.

A Class A amplifier operates over the whole of the input cycle such that the output signal is an exact magnified replica of the input with no clipping. Class A amplifiers are the usual means of implementing small-signal amplifiers. In a Class A circuit, the amplifying element is biased so the device is always conducting to some extent, and is operated over the most linear portion of its characteristic curve. Because the device is always conducting, even if there is no input at all, power is drawn from the power supply. Accordingly, class A amplifiers tend to be relatively in efficient. For large powers this means very large and expensive power supplies and heat sinking.

Class B amplifiers only amplify half of the input wave cycle. As such they create a large amount of distortion, but their efficiency is greatly improved and is much better than Class A. This is because the amplifying element is switched off altogether half of the time, and so cannot dissipate power. A practical circuit using Class B elements is the complementary pair or “push-pull” arrangement. Here, complementary or quasi-complementary devices are used to each amplify the opposite halves of the input signal, which is then recombined at the output. This arrangement gives excellent efficiency, but can suffer from the drawback that there is a small mismatch at the “joins” between the two halves of the signal. This is called crossover distortion. An improvement is to bias the devices so they are not completely off when they're not in use. This approach is called Class AB operation.

In Class AB operation, each device operates the same way as in Class B over half the waveform, but also conducts a small amount on the other half. As a result, the region where both devices simultaneously are nearly off (the “dead zone”) is reduced. The result is that when the waveforms from the two devices are combined, the crossover is greatly minimized or eliminated altogether. Here the two active elements conduct more than half of the time as a means to reduce the cross-over distortions of Class B amplifiers. In the example of the complementary emitter followers a bias network allows for more or less quiescent current thus providing an operating point somewhere between Class A and Class B.

Class C amplifiers conduct less than 50% of the input signal and the distortion at the output is high, but high efficiencies are possible. Some applications (for example, megaphones) can tolerate the distortion. A much more common application for Class C amplifiers is in RF transmitters, where the distortion can be vastly reduced by using tuned loads on the amplifier stage. The input signal is used to roughly switch the amplifying device on and off, which causes pulses of current to flow through a tuned circuit.

An audio amplifier is an electronic amplifier that amplifies low-power audio signals to a level suitable for driving loudspeakers. Audio signals generally refer to signals composed primarily of frequencies between 20 hertz to 20,000 hertz, the human range of hearing. An audio output amplifier is often the final stage in a typical audio playback chain. In a typical audio system, the audio amplifier is usually preceded by low power audio amplifiers which perform tasks like pre-amplification, equalization, tone control, mixing/effects, or audio sources like record players, CD players, and cassette players. Important applications include public address systems, theatrical and concert sound reinforcement, and domestic sound systems. The sound card in a personal computer contains several audio amplifiers (depending on number of channels), as does every stereo or home-theatre system. Most audio amplifiers require these low-level inputs to adhere to line levels. While the input signal to an audio amplifier may measure only a few hundred microwatts, its output may be tens, hundreds, or thousands of watts.

Class AB push-pull circuits are the most common design type found in audio power amplifiers. Class AB is widely considered a good compromise for audio amplifiers, since much of the time the music is quiet enough that the signal stays in the “class A” region, where it is amplified with good fidelity, and by definition if passing out of this region, is large enough that the distortion products typical of class B are relatively small. The crossover distortion can be reduced further by using negative feedback. Class B and AB amplifiers are sometimes used for RF linear amplifiers as well. Class B amplifiers are also favored in battery-operated devices, such as transistor radios.

FIG. 1A is a simplified view diagram illustrating an output portion of a conventional audio system 100. As shown in Figure, an audio frequency signal 102 enters an amplifier 104, which amplifies the signal and drives a microphone 106. A schematic diagram of audio system 100 is shown in FIG. 1B, in which a preamplifier 105 id followed by a CMOS output driver circuit that includes a PMOS driver device 106 and an NMOS driver device 107. The speaker 108 is shown as an equivalent ohmic load, e.g., an 8 ohm resistance load.

Even though conventional audio amplifiers are widely used, they suffer from many limitations. One of the limitations is pop noise or click noise that can be produced in transient states of the amplifier. For example, a pop noises can often be heard during power-on of an audio amplifier. Conventional circuit techniques have been proposed, but they tend to be expensive and are often ineffective.

Accordingly, it is desirable to provide a simple and cost-effective techniques for improving amplifier circuit.

### BRIEF SUMMARY OF THE INVENTION

As noted above, conventional amplifier circuits often suffer from transient related problems, such as pop noise during power-up or power-down. According to embodiments of the present invention, a large RC time-constant generation circuit can be used in arranging the sequence of circuit events in different stages of the amplifier circuit. In other applications, it may also be desirable to have cost-effective circuits to generate large RC time-constant.

The present invention relates generally to electronic circuit techniques. More specifically, embodiments of the present invention relate to techniques for cost-effective circuits for generating RC time-constants. In a specific embodiment, a large RC time-constant circuit includes a capacitor coupled in series with an MOS transistor configured to operate in saturation mode. Merely as an example, such a large RC time-constant circuit has been implemented in an audio amplifier to minimize pop noise generation in an audio system. But it is recognized that the invention can be used in other circuits or systems in which large time-constants are needed, e.g., in delay generation circuits or compensation circuit, etc., in analog or digital systems.

According to an embodiment of the present invention, a circuit for generating a large RC time-constant includes an input node for receiving an input signal making a transition from a first state to a second state characterized by a first time-constant, and an output node for providing an output signal making a transiting from the first state to the second state in response to the input signal. The circuit also includes a first MOS field effect transistor coupled between the input node and the output node. The circuit further includes a first capacitor coupled between the output node and a ground node. A switch circuit is connected to a gate of the first MOS field effect transistor. The switch circuit is configured to bias the MOS field effect transistor to operate in saturation mode during substantially the entire time when the input signal makes the transition from the first state to the second state. For example, for an input signal making a transition from a low state to a high state, the MOS transistor is an NMOS transistor having a gate and a source connected to the output node. In another example, for an input signal making a transition from a high state to a low state, the MOS transistor can be an NMOS transistor having a gate and a source connected to the input node. As a result, the MOS transistor is configured to operate in saturation mode, i.e., the gate-to-drain voltage is smaller than or approximately equal to the threshold voltage. In the saturation mode, the transistor has a large output resistance. Therefore, the transition of the output signal is characterized by a time-constant associated with this large output resistance and the capacitor coupled to the output node. This time-constant can be substantially longer than the first time-constant of the transition of the input signal. Consequently, a cost-effective circuit for generating a large RC time-constant can be realized in an integrated circuit without the chip area penalty of a large on-chip resistance.

In alternative embodiments of the circuit for generating a large RC time-constant described above, a PMOS transistor can be used, instead of the NMOS transistor. In this case, the connections may vary depending on the transistor and signal transition. For example, when the input signal makes a transition from a low state to a high state, the PMOS transistor is configured to have a gate and a source connected to the input node. In some embodiments, the transistor in the RC time-constant circuit can have a threshold voltage of approximately 0V. In these embodiments, when the gate and drain are connected together the gate-to-drain voltage is approximately equal to the threshold voltage. In some embodiments, each of the MOS transistors can be a native transistor. That is, the MOS transistors with low threshold voltage or nearly 0V threshold can be formed using their respective well doping and without additional threshold implant.

In some embodiments of the circuit described above, the capacitor can include an MOS capacitor. For example, the capacitor can include an MOSFET having a drain and a source connected together. In some embodiments the MOS transistor and the capacitor are included in a single integrated circuit chip, whereas in other embodiments, the circuit can also be implemented using discrete components.

In a specific embodiment of the circuit for generating a large RC time-constant described above, the circuit can also include one or more RC time-constant circuit cells coupled between the input node and the first MOS field effect transistor. Each cell has an MOS field effect transistor, a capacitor coupled to the MOS field effect transistor, and a switch circuit coupled to a gate of the MOS field effect transistor for biasing the MOS field effect transistor to operate in saturation mode when the input signal makes the transition from the first state to the second state.

According to another embodiment of the present invention, a circuit for providing a large RC time-constant circuit includes an input terminal for receiving a input signal making a transition from a first state to a second state characterized by a first time-constant; an output terminal for providing an output signal making a transiting from the first state to the second state in response to the input signal, and a plurality of RC time-constant circuit cells connected in series between the input terminal and the output terminal. Each cell includes an MOS field effect transistor, a capacitor coupled to the MOS field effect transistor, and a switch circuit coupled to a gate of the MOS field effect transistor. The switch circuit is configured to connect the gate of the MOS field effect transistor to the output terminal when the input signal makes the transition from a low state to a high state. The switch circuit is also configured to connect the gate of the MOS field effect transistor to the input terminal when the input signal makes a transition from a high state to a low state. In embodiments of the invention, the MOS field effect transistor in each cell is configured to operate in saturation mode during at least a portion of the time period when the input signal makes the transition and the output signal exhibits a time-constant that is substantially longer than the first time-constant of the input signal.

According to yet another embodiment of the present invention, a circuit for providing a large RC time-constant includes an input node for receiving a input signal that is capable of making a transition from a first state to a second state, an output node for providing an output signal capable of making a transiting from the first state to the second state in response to the input signal. The circuit also includes a capacitor coupled between the output node and a ground node and an MOS field effect transistor coupled between the input node and the output node. The MOS field effect transistor is biased to operate in saturation mode during at least a portion of the time when the input signal makes the transition from the first state to the second state. In such configuration, the MOS field effect transistor exhibits a saturation mode drain resistance and the output signal is characterized by a time-constant that is substantially longer than that of the input signal.

In a specific embodiment of the RC time-constant generation circuit described above, the MOS field effect transistor is biased to operate in saturation mode during substantially the entire time when the input signal makes the transition from the first state to the second state. In an embodiment wherein the input signal is input signal is configured to make a transition from a low state to a high state, the MOS transistor can be an NMOS transistor having a gate and a source connected to the output node. In another embodiment wherein the input signal is configured to make a transition from a high state to a low state, the MOS transistor can be an NMOS transistor having a gate and a source connected to input node.

In another specific embodiment of the RC time-constant generation circuit described above, the input signal is configured to make a transition from a low state to a high state, the MOS transistor can be a PMOS transistor having a gate and a source connected to the input node. In yet another embodiment wherein the input signal is configured to make a transition from a high state to a low state, the MOS transistor can be a PMOS transistor having a gate and a source connected to output node. In an embodiment, the capacitor can include an MOS capacitor. Alternatively, the capacitor can include a second MOS transistor having a drain and a source connected together. In an embodiment, the MOS transistor and the capacitor are included in a single integrated circuit chip. In some embodiment, each of the MOS transistor can be a native transistor. In certain embodiment, the circuit can also includes a switch that connects the gate of the transistor to the drain or the source depending on the direction of the transition.

According to an alternative embodiment, the invention provides an integrated circuit that includes a power supply terminal for connecting to a power supply, an output terminal for providing an audio frequency output signal, a large RC time-constant circuit having an input node coupled to the power supply terminal and an output node for providing an operating voltage, and an amplifier circuit coupled to the output node of the large RC time-constant circuit for receiving the operating voltage. The amplifier circuit is configured for providing the audio frequency output signal to the output terminal. In this embodiment, the large RC time-constant circuit includes one or more RC time-constant circuit cells, each cell having a capacitor coupled to an MOS transistor configured to provide a saturation mode output resistance for generating a large time-constant. In some embodiments, each cell further includes a switch circuit that is configured to bias the MOS transistor in the saturation mode during a transition in the power supply voltage. In a specific embodiment, the switch circuit in each cell is configured to connect a gate terminal of the MOS transistor to a drain terminal or a source terminal thereof in response to a change in the power supply voltage.

According to another alternative embodiment, the present invention provides an audio system that includes an input for receiving an audio frequency input signal, a power supply terminal for connecting to a power supply, and an output terminal for providing an audio frequency output signal. The audio system also has a large RC time-constant circuit having an input node coupled to the power supply terminal and an output node for providing an operating voltage. Moreover, the audio system also includes an amplifier circuit coupled to the output node of the large RC time-constant circuit for receiving the operating voltage. The amplifier circuit is configured to provide the audio frequency output signal to the output terminal, which is coupled to a speaker. In an embodiment the large RC time-constant circuit includes one or more RC time-constant circuit cells, each of the cells having a capacitor coupled to an MOS transistor that is configured to provide a saturation mode output resistance for generating a large time-constant. In some embodiments, each of the RC time-constant circuit cells further comprises a switch circuit that is configured to bias the MOS transistor in the saturation mode during a transition in the power supply voltage. In a specific embodiment, the switch circuit in each cell is configured to connect a gate terminal of the MOS transistor to a drain terminal or a source terminal thereof in response to a change in the power supply voltage.

Many benefits are achieved by way of the present invention over conventional techniques. For example, the present technique provides an easy to use design that that is compatible with conventional integrated circuit design and fabrication process technologies. In certain embodiments, the invention provides techniques for generating large RC time-constants. In a specific embodiment, the circuit includes an MOS transistor configured to operate in the saturation mode and provide a large time-constant during signal transition without the penalty of having to use a large on-chip resistance. Merely as an example, an embodiment of the invention is applied to an audio system for suppressing transient noise such as pop noise in an audio amplifier. It is understood, however, the technique can be easily adopted for other applications, such as providing a long delay time between different stages of a circuit. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1A is a simplified view diagram illustrating an output portion of a conventional audio system;

FIG. 1B is a simplified schematic diagram illustrating the conventional audio amplifier of FIG. 1A;

FIGS. 2A and 2B are simplified schematic diagrams illustrating two conventional low pass filters for RC time-constant generation;

FIG. 3 is a simplified schematic diagram illustrating a circuit for large RC time-constant generation according to an embodiment of the present invention;

FIG. 4 a simplified schematic diagram illustrating a circuit for large RC time-constant generation according to another embodiment of the present invention;

FIG. 5 is a simplified schematic diagram illustrating a circuit for large RC time-constant generation according to an alternative embodiment of the present invention;

FIG. 6 is a simplified schematic diagram illustrating a circuit for large RC time-constant generation according to another alternative embodiment of the present invention;

FIG. 7 is a simplified schematic diagram illustrating a cascaded circuit for large RC time-constant generation according to an embodiment of the present invention;

FIG. 8 is a simplified schematic diagram illustrating a cascaded circuit for large RC time-constant generation according to another embodiment of the present invention;

FIG. 9 is a simplified schematic diagram illustrating an audio system including a circuit for large RC time-constant generation according to an embodiment of the present invention; and

FIG. 10 is a simplified schematic diagram illustrating an audio system including a circuit for large RC time-constant generation according to another embodiment of the present invention.

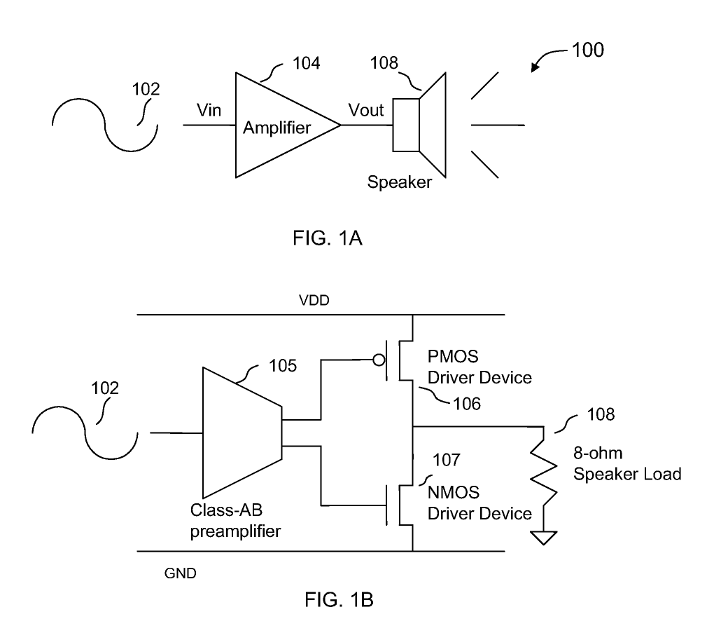

### DETAILED DESCRIPTION OF THE INVENTION

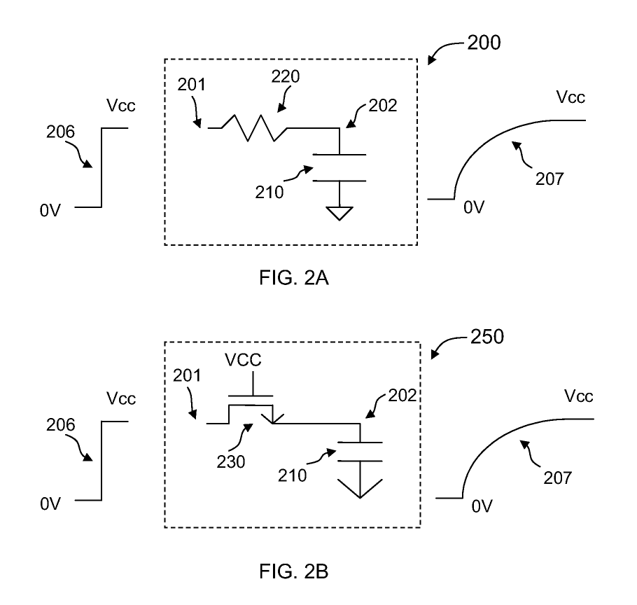

FIGS. 2A and 2B are simplified schematic diagrams illustrating two conventional low pass filters for RC time-constant generation. In FIG. 2A, resistor 220 and capacitor 210 forms an RC circuit having a time-constant related to R*C, a product of the resistance of resistor 320 and the capacitance of capacitor 210. As input signal 206 makes the transition from 0V to Vcc, for example, output signal 207 also makes a transition from 0V to a voltage close to Vcc. As shown, the output signal rises more slowly than the input signal 206, the rise time is related the time-constant RC. In FIG. 2B, the resistor is replaced by an NMOS transistor 230 with a gate voltage of Vcc. In this configuration, transistor 230 functions like a resistor, and circuit 250 operates like an RC filter. In both circuits 200 and 250, the resistance is limited by the size of the resistor or transistor. To generate a large time-constant, one way to increase the resistance both circuit is to use a resistor or transistor having a long device dimension. However, this is highly undesirable, because of the penalty in chip area of an integrated circuit.

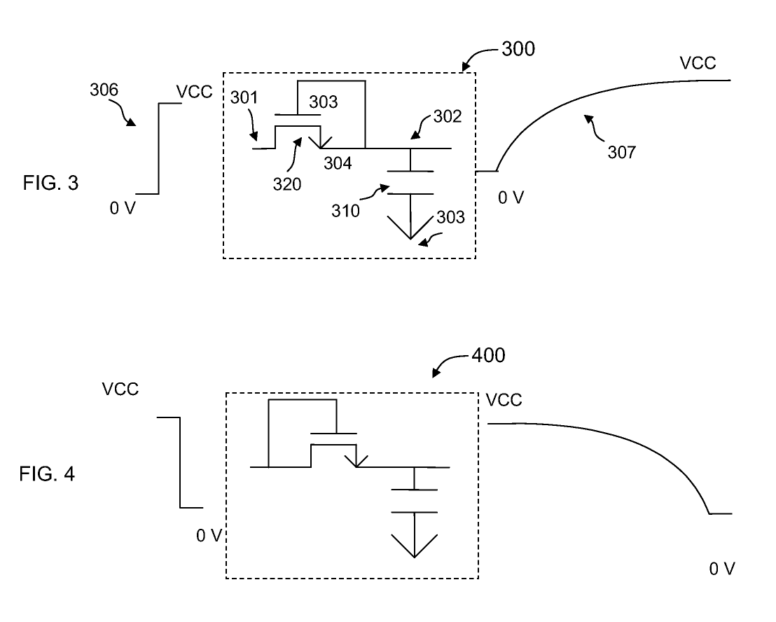

FIG. 3 is a simplified schematic diagram illustrating a circuit for large RC time-constant generation according to an embodiment of the present invention. As shown, a circuit 300 for providing a large RC time-constant includes an input node 301 for receiving an input signal that is capable of making a transition from a first input state to a second input state, and an output node 302 for providing an output signal capable of making a transiting from the first output state to the second output state in response to the input signal. The large RC time-constant generation circuit 300 also includes a capacitor 310 coupled between the output node and a ground node 303 and an MOS field effect transistor 320 coupled between the input node 301 and the output node 302.

In FIG. 3, input signal 306 is shown as making a transition from 0V to Vcc with a relatively short first time-constant, and output node 307 is also shown as making a transition from 0V to Vcc with a second time-constant that is substantially longer than the first time-constant. According to an embodiment, MOS field effect transistor 320 is biased to operate in saturation mode during at least a portion of the time when the input signal makes the transition from the first state (e.g., 0V) to the second state (e.g., Vcc). As shown in FIG. 3, MOS field effect transistor 320 is an NMOS transistor with gate 303 and source 304 connected together. As the drain 301 is raised to Vcc with input signal 306, the drain voltage at 301 is higher than the gate voltage at 303, maintaining transistor 320 in saturation mode. As a result, transistor 320 exhibits a relatively high saturation mode output resistance. Therefore, the output signal 307 is characterized by a time-constant that associated with the large saturation mode output resistance and capacitor 310. Consequently the output signal rises in response to the input signal with the second time-constant that can be substantially longer than the first time-constant associated with the input signal.

In the embodiment of the RC time-constant generation circuit described above, the MOS field effect transistor is biased to operate in saturation mode during substantially the entire time when the input signal makes the transition from the first state to the second state. In a specific embodiment, transistor 320 can have a threshold voltage of approximately 0V. In this case, transistor 320 stays turned on during signal transition with its gate 303 and source 304 tied together. In another embodiment, the threshold voltage of transistor 320 can be positive and transistor 320 may be operating in subthreshold region with reduced current and can have an even longer time-constant. A low threshold voltage or nearly zero volt threshold voltage can be obtain by using a native transistor structure, which can be formed by maintaining a background well doping concentration in the channel region and without a threshold voltage ion implantation step.

In the embodiment wherein the input signal is configured to make a transition from a low state to a high state, such as illustrated in FIG. 3, the MOS transistor can be an NMOS transistor having a gate and a source connected to the output node. In another embodiment wherein the input signal is configured to make a transition from a high state to a low state, the MOS transistor can be an NMOS transistor having a gate and a source connected to the input node. An example of this configuration is shown in FIG. 4, which is a simplified schematic diagram illustrating a circuit 400 for large RC time-constant generation according to another embodiment of the present invention. As shown, circuit 400 is similar to circuit 300 in FIG. 3, except the signal transitions and transistor terminal connections are reversed. In this case, the transistor is also configured to operate in saturation mode to provide a large output time-constant.

Accordingly to embodiments of the present invention, a large resistance and, hence, can be obtained with a transistor configured to operate in saturation mode. The transistor can also be a PMOS transistor. In a specific embodiment of the RC time-constant generation circuit, in which the input signal is configured to make a transition from a low state to a high state, the MOS transistor can be a PMOS transistor having a gate and a source connected to the input node. In yet another embodiment wherein the input signal is configured to make a transition from a high state to a low state, the MOS transistor can be a PMOS transistor having a gate and a source connected to output node. In an integrated circuit, the capacitor can include an MOS capacitor. Alternatively, the capacitor can include a second MOS transistor having a drain and a source connected together. In some embodiments, the MOS transistor can be a native transistor, as noted above.

In an embodiment, the large time-constant generation circuit can be implemented in a single integrated circuit chip to provide a large time-constant without the penalty of a large on-chip resistance. As a example, a time-constant of 8 msec can be achieved with an on-chip capacitor of 10 pF and a resistance of 800 MΩ. Such a resistance can be provided by, e.g., a transistor of W=0.42 μm by L=20 μm cascaded 256 times for total area of 2150 μm² according to an embodiment of the present invention. In contrast, a convention on-chip diffusion resistor of 800 MΩ can take a chip area of as much as W=0.42 μm by L=20 μm cascaded 285,000 times, totaling 1000 times larger area. Therefore, a cost-effective large time-constant circuit can be provided using the embodiments described in FIGS. 3 and 4.

In some applications, it may be desirable to allow signal transition from both directions, i.e., from a low state to a high state, and from a high state to a low state. In some embodiments, the present invention provides a large time-constant generation circuit that is configured to operate with signal transitions in both directions. In a specific embodiment, the circuit can include a switch circuit that connects the gate of the transistor to either the drain or the source depending on the direction of the transition.

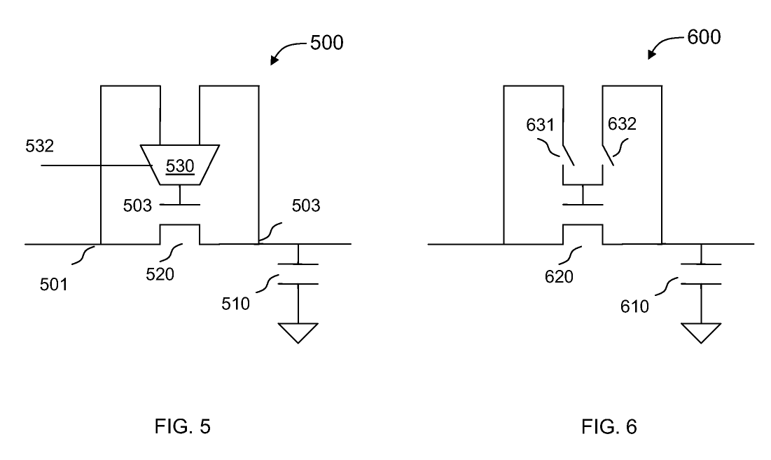

FIG. 5 is a simplified schematic diagram illustrating a circuit 500 for large RC time-constant generation according to an alternative embodiment of the present invention. As shown, circuit 500 includes transistor 520 and capacitor 510 which can be similar to transistor 320 and capacitor 310, respectively, in FIG. 3. Additionally, circuit 500 also includes a switch circuit 530 implemented as a multiplexer under control of a control signal 532. Multiplexer 530 is configured to connect gate 503 of transistor 530 to either of the transistor terminals 501 and 503, depending on the direction of input signal transition. As shown in FIGS. 3 and 4, by changing such connections, the transistor can be configured to operate in saturation mode during input signal transition in either direction.

For example, for an input signal making a transition from a low state to a high state, the MOS transistor is an NMOS transistor having a gate and a source connected to the output node. In another example, for an input signal making a transition from a high state to a low state, the MOS transistor can be an NMOS transistor having a gate and a source connected to the input node. As a result, the MOS transistor is configured to operate in saturation mode, i.e., the gate-to-drain voltage is smaller than or approximately equal to the threshold voltage. In the saturation mode, the transistor has a large output resistance. Therefore, the transition of the output signal is characterized by a time-constant associated with this large output resistance and the capacitor coupled to the output node. This time-constant can be substantially longer than the first time-constant of the transition of the input signal. Consequently, a cost-effective circuit for generating a large RC time-constant can be realized in an integrated circuit without the chip area penalty of a large on-chip resistance.

In alternative embodiments of the circuit for generating a large RC time-constant described above, a PMOS transistor can be used, instead of the NMOS transistor. In this case, the connections may vary depending on the transistor and signal transition. For example, when the input signal makes a transition from a low state to a high state, the PMOS transistor is configured to have a gate and a source connected to the input node. In some embodiments, the transistor in the RC time-constant circuit can have a threshold voltage of approximately 0V. In these embodiments, when the gate and drain are connected together the gate-to-drain voltage is approximately equal to the threshold voltage. In some embodiments, each of the MOS transistors can be a native transistor. That is, the MOS transistors with low threshold voltage or nearly 0V threshold can be formed using their respective well doping and without additional threshold implant.

In some embodiments of the circuit described above, the capacitor can include an MOS capacitor. For example, the capacitor can include an MOSFET having a drain and a source connected together. In some embodiments the MOS transistor and the capacitor are included in a single integrated circuit chip, whereas in other embodiments, the circuit can also be implemented using discrete components.

In a specific embodiment of the circuit for generating a large RC time-constant described above, the circuit can also include one or more RC time-constant circuit cells coupled between the input node and the first MOS field effect transistor. Each cell has an MOS field effect transistor, a capacitor coupled to the MOS field effect transistor, and a switch circuit coupled to a gate of the MOS field effect transistor for biasing the MOS field effect transistor to operate in saturation mode when the input signal makes the transition from the first state to the second state.

FIG. 6 is a simplified schematic diagram illustrating a circuit 600 for large RC time-constant generation according to another alternative embodiment of the present invention. As shown, circuit 600 is similar to circuit 500, with the switch circuit 630 shown as two switches 631 and 632 under control of a control signal (not shown). A large RC time-constant is provided when the transistor is configured to operate in saturation mode during signal transition.

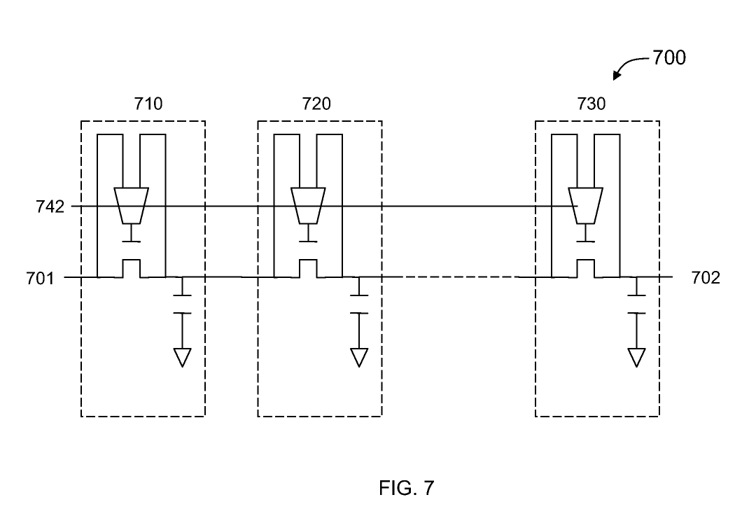

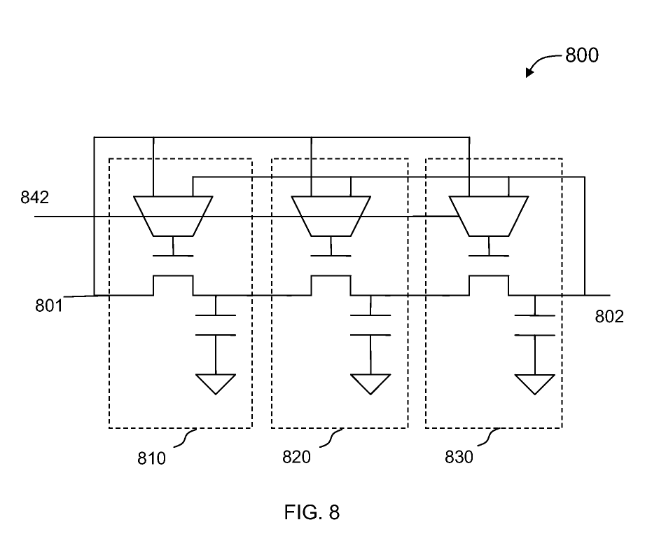

FIG. 7 is a simplified schematic diagram illustrating a circuit 700 for large RC time-constant generation according to an embodiment of the present invention. As shown, circuit 700 for providing a large RC time-constant circuit includes an input terminal 701 for receiving a input signal making a transition from a first state to a second state characterized by a first time-constant; an output terminal 702 for providing an output signal making a transiting from the first state to the second state in response to the input signal, and a plurality of RC time-constant circuit cells 710, 720, 730, etc. connected in series between the input terminal 701 and the output terminal 702. The transitions of input and output signals can be similar to those described above in reference to FIGS. 3 and 4.

In FIG. 7, each cell 710, 720, or 730 is similar to circuit 500 of FIG. 5. Specifically, each cell includes an MOS field effect transistor, a capacitor coupled to the MOS field effect transistor, and a switch circuit coupled to a gate of the MOS field effect transistor. The switch circuit is configured to connect the gate of the MOS field effect transistor to the output terminal of the cell when the input signal makes the transition from a low state to a high state. The switch circuit is also configured to connect the gate of the MOS field effect transistor to the input terminal of the cell when the input signal makes a transition from a high state to a low state. The switch circuit in each cell changes the connections in response to control signal 742. In embodiments of the invention, the MOS field effect transistor in each cell is configured to operate in saturation mode during at least a portion of the time period when the input signal makes the transition and the output signal exhibits a time-constant that is substantially longer than the first time-constant of the input signal.

FIG. 8 is a simplified schematic diagram illustrating a cascaded circuit 800 for large RC time-constant generation according to another embodiment of the present invention. As shown, circuit 800 is similar to circuit 700 of FIG. 7 in that circuit 800 also includes a plurality of large time-constant cells, such as 810, 820, and 830, etc. As shown, each cell is again similar to circuit 500 in FIG. 5 and includes a transistor, a capacitor, and a switch circuit. Each transistor is configured to operate in the saturation region to provide a large resistance such as each cell can provide a large time-constant. The combination of the plurality of cells are configured an even larger time-constant. It is noted that in FIG. 8, each of the switch circuits are configured to connect the gate of each transistor directly to either the input terminal 801 of circuit 800 or the output terminal 802 of circuit 800. This is in contract to circuit 700 of FIG. 7 in which each of the switch circuit is configured to connect a gate of a transistor to either the input terminal of the cell or the output terminal of the cell. In FIG. 8, the switch circuit in each of cells, 810, 820, and 830, etc., configures the cell in response to control signal 842.

According to embodiments of the invention, each of the embodiments in FIGS. 3-8 can be implemented in a single integrated circuit chip. In a specific embodiment, the invention provides an integrated circuit that includes a power supply terminal for connecting to a power supply, an output terminal for providing an audio frequency output signal, a large RC time-constant circuit having an input node coupled to the power supply terminal and an output node for providing an operating voltage, and an amplifier circuit coupled to the output node of the large RC time-constant circuit for receiving the operating voltage. The amplifier circuit is configured for providing the audio frequency output signal to the output terminal. In this embodiment, the large RC time-constant circuit includes one or more RC time-constant circuit cells, each cell having a capacitor coupled to an MOS transistor configured to provide a saturation mode output resistance for generating a large time-constant. In some embodiments, each cell further includes a switch circuit that is configured to bias the MOS transistor in the saturation mode during a transition in the power supply voltage. In a specific embodiment, the switch circuit in each cell is configured to connect a gate terminal of the MOS transistor to a drain terminal or a source terminal thereof in response to a change in the power supply voltage. An application of the integrated circuit discussed above is an audio system described below.

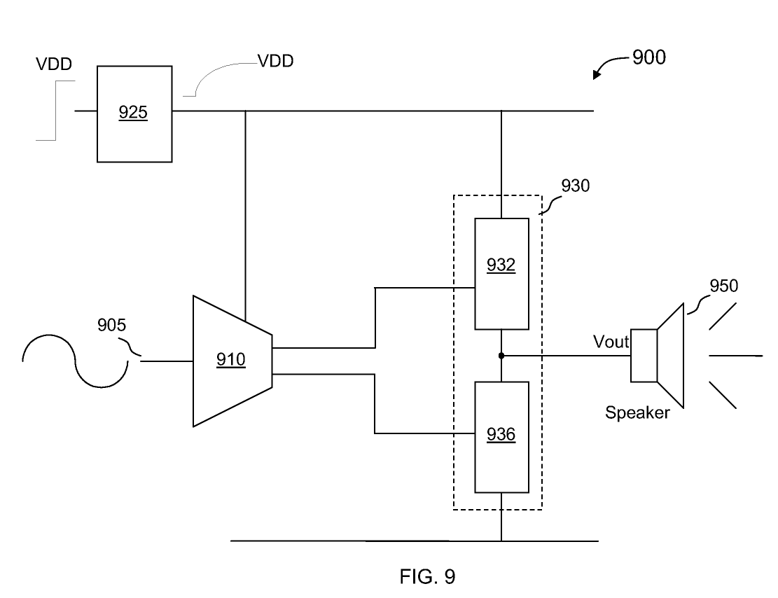

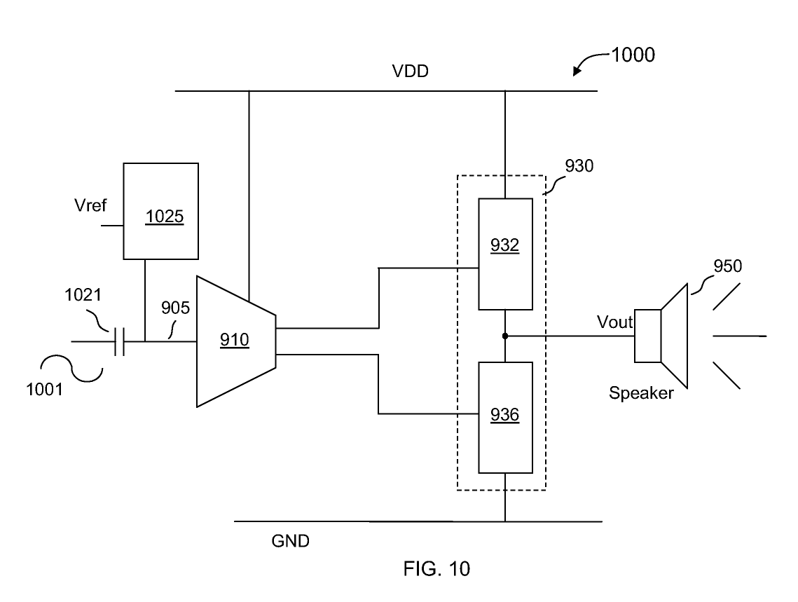

FIG. 9 is a simplified schematic diagram illustrating an audio system 900 including a circuit 925 for large RC time-constant generation according to an embodiment of the present invention. This diagram is merely an example, which should not unduly limit the scope of the claims herein. As shown, audio system 900 includes a preamplifier 910, an output amplifier 930, and a speaker 950. The preamplifier 910 received audio signal 905, which enters into audio system through an input (not shown). In some embodiments, audio signal 905 may be processes in other parts of the audio system before being received by preamplifier 910. In an embodiment, preamplifier 910 can be a conventional class AB audio amplifier that receives audio frequency signal 905 and delivers amplified signals to the output amplifier 930.

In an embodiment, output amplifier 930 includes an upper stage 932 and a lower stage 934. In a specific embodiment, output driver circuit 930 may include a CMOS output driver circuit. In an embodiment, large RC time-constant generation circuit 925 is coupled to a power supply voltage VDD and provides a bias voltage to the circuits in the amplifier. Depending on the embodiment, the large RC time-constant generation circuit 925 may be similar to one of the large time-constant circuits described above with reference to FIGS. 3-8 to provide a large time-constant and a slow rising supply voltage. In a specific application, this configuration can be used to reduce or eliminate pop noise when the audio amplifier is powered up.

Thus, according to an embodiment, the present invention provides an audio system that includes an input for receiving an audio frequency input signal, a power supply terminal for connecting to a power supply, and an output terminal for providing an audio frequency output signal. The audio system also has a large RC time-constant circuit having an input node coupled to the power supply terminal and an output node for providing an operating voltage. Moreover, the audio system also includes an amplifier circuit coupled to the output node of the large RC time-constant circuit for receiving the operating voltage. The amplifier circuit is configured to provide the audio frequency output signal to the output terminal, which is coupled to a speaker. In an embodiment the large RC time-constant circuit includes one or more RC time-constant circuit cells, each of the cells having a capacitor coupled to an MOS transistor that is configured to provide a saturation mode output resistance for generating a large time-constant. In some embodiments, each of the RC time-constant circuit cells further comprises a switch circuit that is configured to bias the MOS transistor in the saturation mode during a transition in the power supply voltage. In a specific embodiment, the switch circuit in each cell is configured to connect a gate terminal of the MOS transistor to a drain terminal or a source terminal thereof in response to a change in the power supply voltage.

FIG. 10 is a simplified schematic diagram illustrating an audio system 1000 including a circuit for large RC time-constant generation 1025 according to another embodiment of the present invention. As shown, audio system 1000 of FIG. 10 is similar to audio system 900 of FIG. 9, with similar parts of the system designated by identical numerals. One difference is that in audio system 1000, the circuit for large RC time-constant generation 1025 is coupled to a common-mode input 905 of amplifier 910, and provides a large time-constant in raising the common mode input voltage to a reference voltage Vref. In a specific embodiment, audio signal 1001 can be coupled to a coupling capacitor 1021. In another alternative embodiment, a large RC time-constant circuit can be coupled to an output amplifier for providing bias voltage to the output amplifier after a desirable delay.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

What is claimed is:

1. A circuit for providing a large RC time-constant, the circuit comprising:
an input node for receiving an input signal making a transition from a first state to a second state, the transition being characterized by a first time-constant;
an output node for providing an output signal making a transiting from the first state to the second state in response to the input signal;
a first MOS field effect transistor coupled between the input node and the output node;
a first capacitor coupled between the output node and a ground node;
a switch circuit connected to a gate of the first MOS field effect transistor, the switch circuit configured to bias the MOS field effect transistor to operate in saturation mode during substantially the entire time when the input signal makes the transition from the first state to the second state,
whereby the transition of the output signal is characterized by a time-constant substantially longer than the first time-constant of the input signal.

2. The circuit of claim 1 further comprising:
one or more RC time-constant circuit cells coupled between the input node and the first MOS field effect transistor, each cell including:
an MOS field effect transistor having a threshold voltage of approximately 0V;
a capacitor coupled to the MOS field effect transistor; and
a switch circuit coupled to a gate of the MOS field effect transistor, the switch circuit biasing the MOS field effect transistor to operate in saturation mode when the input signal makes the transition from the first state to the second state,

3. The circuit of claim 1 wherein the input signal is input signal is configured to make a transition from a low state to a high state, wherein the MOS transistor is an NMOS transistor having a gate and a source connected to the output node.

4. The circuit of claim 1 wherein the input signal is configured to make a transition from a high state to a low state, wherein the MOS transistor is an NMOS transistor having a gate and a source connected to the input node.

5. The circuit of claim 1 wherein the input signal is configured to make a transition from a low state to a high state, wherein the MOS transistor is a PMOS transistor having a gate and a source connected to the input node.

6. The circuit of claim 1 wherein the input signal is configured to make a transition from a high state to a low state, wherein the MOS transistor is a PMOS transistor having a gate and a source connected to output node.

7. The circuit of claim 1 wherein the capacitor comprises an MOS capacitor.

8. The circuit of claim 1 wherein the capacitor comprises an MOSFET having a drain and a source connected together.

9. The circuit of claim 1 wherein the MOS transistor and the capacitor are included in a single integrated circuit chip.

10. The circuit of claim 1 wherein each of the MOS transistors is native transistor.

11. A circuit for providing a large RC time-constant circuit, comprising:
an input terminal for receiving a input signal making a transition from a first state to a second state, the transition being characterized by a first time-constant;
an output terminal for providing an output signal making a transiting from the first state to the second state in response to the input signal;
a plurality of RC time-constant circuit cells connected in series between the input terminal and the output terminal, each cell including:
an MOS field effect transistor;
a capacitor coupled to the MOS field effect transistor; and
a switch circuit coupled to a gate of the MOS field effect transistor, the switch circuit configured to connect the gate of the MOS field effect transistor to the output terminal when the input signal makes the transition from a low state to a high state, the switch circuit also configured to connect the gate of the MOS field effect transistor to the input terminal when the input signal makes a transition from a high state to a low state,
whereby the MOS field effect transistor in each cell is configured to operate in saturation mode during at least a portion of the time period when the input signal makes the transition and the output signal exhibits a time-constant that is substantially longer than the first time-constant of the input signal.

12. A circuit for providing a large RC time-constant, the circuit comprising:
an input node for receiving a input signal that is capable of making a transition from a first state to a second state;
an output node for providing an output signal capable of making a transiting from the first state to the second state in response to the input signal;
a capacitor coupled between the output node and a ground node; and
an MOS field effect transistor and being coupled between the input node and the output node, the MOS field effect transistor being biased to operate in saturation mode during substantially the entire time when the input signal makes the transition from the first state to the second state,
whereby the MOS field effect transistor exhibits a saturation mode drain resistance and the output signal is characterized by a time-constant that is substantially longer than that of the input signal.

13. The circuit of claim 12 wherein the input signal is input signal is configured to make a transition from a low state to a high state,
wherein the MOS transistor is an NMOS transistor having a gate and a source connected to the output node.

14. The circuit of claim 12 wherein the input signal is configured to make a transition from a high state to a low state,
wherein the MOS transistor is an NMOS transistor having a gate and a source connected to input node.

15. The circuit of claim 12 wherein the input signal is configured to make a transition from a low state to a high state,
wherein the MOS transistor is a PMOS transistor having a gate and a source connected to the input node.

16. The circuit of claim 12 wherein the input signal is configured to make a transition from a high state to a low state,
wherein the MOS transistor is a PMOS transistor having a gate and a source connected to output node.

17. The circuit of claim 12 wherein each of the MOS transistor is native transistor.

18. The circuit of claim 12 further comprising a swtich—that changes the bias depending on the transition up-down or down-up.

19. An integrated circuit, comprising:
a power supply terminal for connecting to a power supply;
an output terminal for providing an audio frequency output signal;
a large RC time-constant circuit having an input node coupled to the power supply terminal and an output node for providing an operating voltage; and
an amplifier circuit coupled to the output node of the large RC time-constant circuit for receiving the operating voltage, the amplifier circuit providing the audio frequency output signal to the output terminal,
wherein the large RC time-constant circuit including one or more RC time-constant circuit cells, each cell having a capacitor coupled to an MOS transistor configured to provide a saturation mode output resistance for generating a large time-constant.

20. The integrated circuit of claim 19 where in each cell further comprises a switch circuit that is configured to bias the MOS transistor in the saturation mode during a transition in the power supply voltage.

21. The integrated circuit of claim 20 where the switch circuit in each cell is configured to connect a gate terminal of the MOS transistor to a drain terminal or a source terminal thereof in response to a change in the power supply voltage.

22. An audio system, comprising:
an input for receiving an audio frequency input signal;
a power supply terminal for connecting to a power supply;
an output terminal for providing an audio frequency output signal;
a large RC time-constant circuit having an input node coupled to the power supply terminal and an output node for providing an operating voltage;
an amplifier circuit coupled to the output node of the large RC time-constant circuit for receiving the operating voltage, the amplifier circuit providing the audio frequency output signal to the output terminal; and
a speaker coupled to the output terminal,
wherein the large RC time-constant circuit includes one or more RC time-constant circuit cells, each cell having a capacitor coupled to an MOS transistor configured to provide a saturation mode output resistance for generating a large time-constant.

23. The audio system of claim 22 wherein each of the RC time-constant circuit cells further comprises a switch circuit that is configured to bias the MOS transistor in the saturation mode during a transition in the power supply voltage.

24. The audio system of claim 23 where the switch circuit in each cell is configured to connect a gate terminal of the MOS transistor to a drain terminal or a source terminal thereof in response to a change in the power supply voltage.
